(19) United States
(12) Patent Application Publication
(10) Pub. No.: US 2005/0209832 A1
(43) Pub. Date: Sep. 22, 2005

(54) System and method for developing embedded systems

(75) Inventors: Kas Kasravi, West Bloomfield, MI (US); Fred Cummins, Farmington Hills, MI (US); Edwin Suckstorff JR., Troy, MI (US); Michael J. Taljonick, Davison, MI (US)

Correspondence Address: DOCKET CLERK, DM/EDS, P.O. DRAWER 800889, DALLAS, TX, 75380, US

(73) Assignee: Electronic Data Systems Corporation, Plano, TX (US)

(21) Appl. No.: 11/050,641

(22) Filed: Feb. 3, 2005

Related U.S. Application Data
(60) Provisional application No. 60/542,169, filed on Feb. 5, 2004.

(51) Int. Cl. G06F 9/44; G06F 17/50; G01D 18/00; G06F 19/00; G01M 19/00; G01P 21/00; G01D 21/00; G01R 35/00

(52) U.S. Cl. 703/1; 702/85

(57) ABSTRACT

A method for improving the development of embedded systems. A preferred process includes a taxonomy for embedded systems that serves as the unified communications standard for all development activities, a digital repository of historical solutions (frameworks), and an expert system to select/configure/generate the initial framework based on a knowledge-base (rules) of configuration best-practices and using an inference engine.

### CROSS-REFERENCE TO RELATED APPLICATIONS

The present application claims priority to United States Provisional Patent Application claims priority to U.S. Provisional Patent Application 60/542,169, filed Feb. 5, 2004, which is hereby incorporated by reference.

### TECHNICAL FIELD OF THE INVENTION

The present invention is directed, in general, to the field of embedded systems.

### BACKGROUND OF THE INVENTION

Embedded Systems involve software/hardware applications in consumer products and industrial equipment, such as cars, toys, medical equipment etc. Trends indicate that embedded systems development is a rapidly growing market opportunity. Embedded systems are systems whose function and outputs are controlled by decision algorithms based on inputs. Embedded systems may or may not,
use an operating system (more than half do not);
have user interfaces; and
be connected (wired, wireless).

Development of embedded systems differs from conventional computer applications. In embedded systems, the developer works more closely with hardware and the end product, programming is at a lower level, there is more complex algorithm development, and more extensive testing. Unlike conventional software, the logic in many embedded systems cannot be updated after release, which underscores extensive validation prior to production.

In a typical development process, the requirements are analyzed against existing solutions, an existing framework (source code, components, documents etc.) is selected as a starting point, the framework is customized over a period of time and multiple alternatives are produced and tested, and the alternatives are calibrated until the optimal configuration is achieved and validated. The process often involves multiple iterations. The developers need to review extensive documentation, code walk-through, and testing in each phase.

Model-Driven Architecture (MDA), as known to those of skill in the art, is a new way of writing specifications and developing applications, based on a platform-independent model (PIM). A complete MDA specification consists of a definitive platform-independent base UML® model, plus one or more platform-specific models (PSM) and interface definition sets, each describing how the base model is implemented on a different middleware platform. A complete MDA application consists of a definitive PIM, plus one or more PSMs and complete implementations, one on each platform that the application developer decides to support.

MDA development focuses first on the functionality and behavior of a distributed application or system, undistorted by idiosyncrasies of the technology or technologies in which it will be implemented. MDA divorces implementation details from business functions. Thus, it is not necessary to repeat the process of modeling an application or system's functionality and behavior each time a new technology (e.g., XML/SOAP) comes along. Other architectures are generally tied to a particular technology. With MDA, functionality and behavior are modeled once and only once. Mapping from a PIM through a PSM to the supported MDA platforms will be implemented by tools, easing the task of supporting new or different technologies.

Developing embedded systems is knowledge, resource, and cost intensive. Due to the expanding market opportunity, off-shore competition, and shorter product development cycles, there is a need for more optimal processes for developing embedded systems, which could leverage reuse and best practices to help generate solutions in a shorter period of time and at a lower cost. There is, therefore, a need in the art for a system and process for developing embedded systems.

### SUMMARY OF THE INVENTION

A preferred embodiment offers a method for improving the development of embedded systems. A preferred process includes a taxonomy for embedded systems that serves as the unified communications standard for all development activities, a digital repository of historical solutions (frameworks), and an expert system to select/configure/generate the initial framework based on a knowledge-base (rules) of configuration best-practices and using an inference engine.

The foregoing has outlined rather broadly the features and technical advantages of the present invention so that those skilled in the art may better understand the detailed description of the invention that follows. Additional features and advantages of the invention will be described hereinafter that form the subject of the claims of the invention. Those skilled in the art will appreciate that they may readily use the conception and the specific embodiment disclosed as a basis for modifying or designing other structures for carrying out the same purposes of the present invention. Those skilled in the art will also realize that such equivalent constructions do not depart from the spirit and scope of the invention in its broadest form.

Before undertaking the DETAILED DESCRIPTION OF THE INVENTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases.

### BRIEF DESCRIPTION OF THE DRAWINGS

For a more complete understanding of the present invention, and the advantages thereof, reference is now made to the following descriptions taken in conjunction with the accompanying drawings, wherein like numbers designate like objects, and in which:

FIG. 1 illustrates a development process;

FIG. 2 illustrates a development process in accordance with a preferred embodiment; and

FIG. 3 graphically illustrates a sample taxonomy.

### DETAILED DESCRIPTION OF THE INVENTION

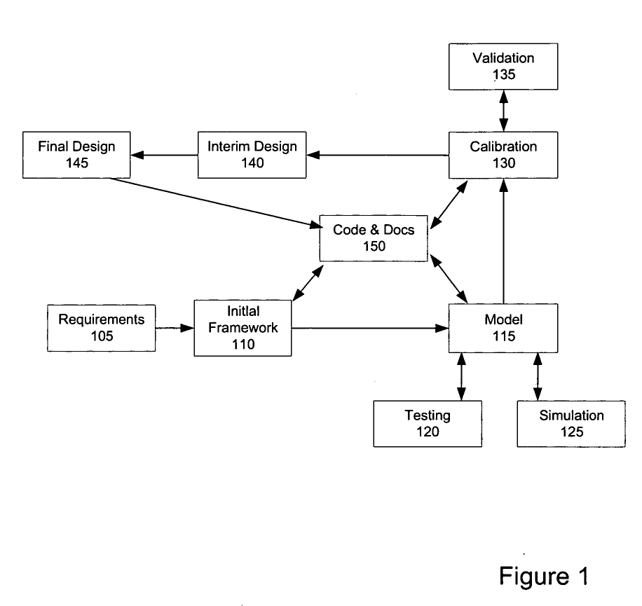

FIGS. 1-3, discussed below, and the various embodiments used to describe the principles of the present invention in this patent document are by way of illustration only and should not be construed in any way to limit the scope of the invention. Those skilled in the art will understand that the principles of the present invention may be implemented in any suitably arranged device. The numerous innovative teachings of the present application will be described with particular reference to the attached figures.

A preferred embodiment offers a method for improving the development of embedded systems. A preferred process includes a taxonomy for embedded systems that serves as the unified communications standard for all development activities, a digital repository of historical solutions (frameworks), and an expert system to select/configure/generate the initial framework based on a knowledge-base (rules) of configuration best-practices and using an inference engine.

Some features of this invention include a unified representation of the terminology and concepts used in the development of embedded systems, a reusable and searchable repository of historical frameworks, consisting of the plurality of framework components, such as but not limited to source code, components, documentations, test plans, and calibration parameters, an automated method for generating the initial design (framework) based on the requirements, and an improved customization process that provides interactive tools and models, and to capture and reuse best-practices.

A conventional development process is illustrated in FIG. 1. First, define requirements 105. Next, create an initial framework 110, with reference to existing code and documentation 150. Next, customize the framework model 115, also with reference to existing code and documentation 150, including testing 120 and simulation 125.

Next, the framework is calibrated 130 with reference to existing code and documentation 150, including a validation 135. Based on the framework, first an initial design 140 then a final design 145 are created. The final design 145 is stored in the existing code and documentation 150.

Rules engines (also known as expert systems) are a method used to implement knowledge-based systems. In these systems, the domain knowledge is represented by IF-THEN rules (heuristics) and used in forward or backward chaining modes by an inference engine. Expert systems were pioneered by Edward Feigenbaum of Stanford University in the 1960s. His chemistry system, DENDRAL, used the chemical knowledge gathered from Nobel Prize winning scientist, Joshua Ledenberg, best known today as the father of genetic engineering.

The inference engine is software that uses mathematical logic to draw conclusions and is the control structure of a system. Inference engines are not application specific and can be purchased from tool vendors.

The knowledge base is a set of IF-THEN rules that contain the high-level principles about the domain. Knowledge bases are very application specific and can be built by knowledge engineers using commercial products.

The inference engine and the knowledge base are the permanent parts of the system. The rule-based system can be used many times with different data entered into it to solve different problems. The system's users enter data into working memory and (working memory is a list of facts about a topic can be expanded during the operation of a rule-based system) the inference engine takes the data from working memory, applies the rules in the knowledge base to it, and deduces more facts. These new facts are then added back into the working memory.

There are two types of knowledge represented in expert systems, facts and relationships. The following statement shows the logical relationship between two concepts, age and adulthood: A typical fact states, “John is 30.” A relationship says, “If a human is over 21, then the human is an adult.”

Facts tend to be put into objects in most rule-based systems. Relationships are put into rules. Rules are used to capture conditional knowledge, such as what actions to perform under various conditions, or what causes lead to various symptoms. Rules are, in effect, logic statements that use the implication connective (=>), and can involve quantifiers and variables.

Clauses are the building blocks of rules. A rule joins two clauses (simple or compound) and states that the truth of the first clause implies the truth of the second clause.

When compared with procedural programs, a rule-based system is structured as follows: Data structures+Algorithms=Procedural Program; Knowledge (rules)+Inference=Expert System.

Algorithms are at the center of procedural computing. Most application developers have been trained to think in terms of algorithms and their knowledge is often best expressed on the computer in algorithmic terms. Flow charts often represent algorithms and are the process side of computing systems.

Heuristics as used in expert systems are rules-of-thumb that often work, though not always. Inherent to most expert systems that implement heuristics is the notion of uncertainty. Most expert systems provide support for reasoning even under conditions of uncertainty or missing information.

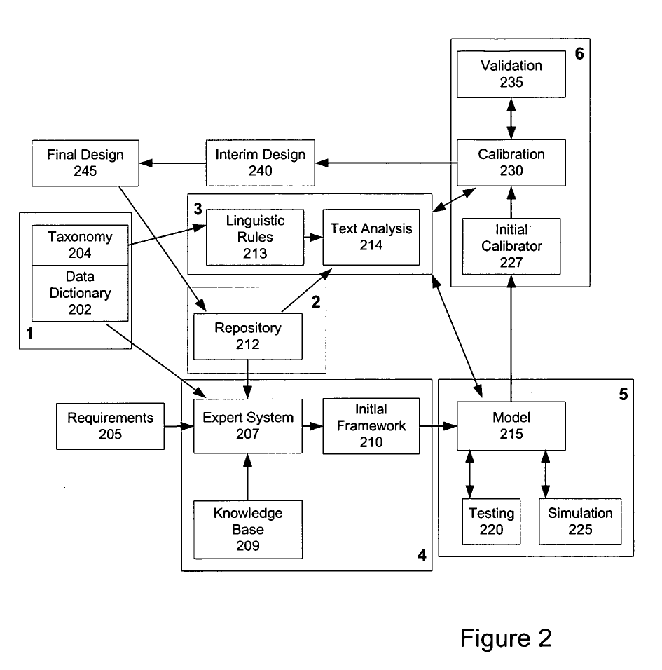

An improved development process is illustrated in FIG. 2. In this figure, several large process blocks are shown each including at least one subprocess.

Block 1 includes processes to develop a data dictionary 202 and subsequently a taxonomy 204 for embedded systems. This taxonomy 204 contains all the key elements and their hierarchy and relationships, and serves as the unified communications standard for all development activities.

In embedded systems, the developers use common and specialized terminology to communicate with each other. The proposed invention needs to implement the same set of terms, in context, to capture, organize, and analyze the information.

Linguistic systems and knowledge-based systems such as those described herein require a taxonomy to organize the domain information in a consistent fashion. Taxonomy is a hierarchical set of concepts that organize a data dictionary into categories and sub-categories. Thus, the terms in the data dictionary are now in context.

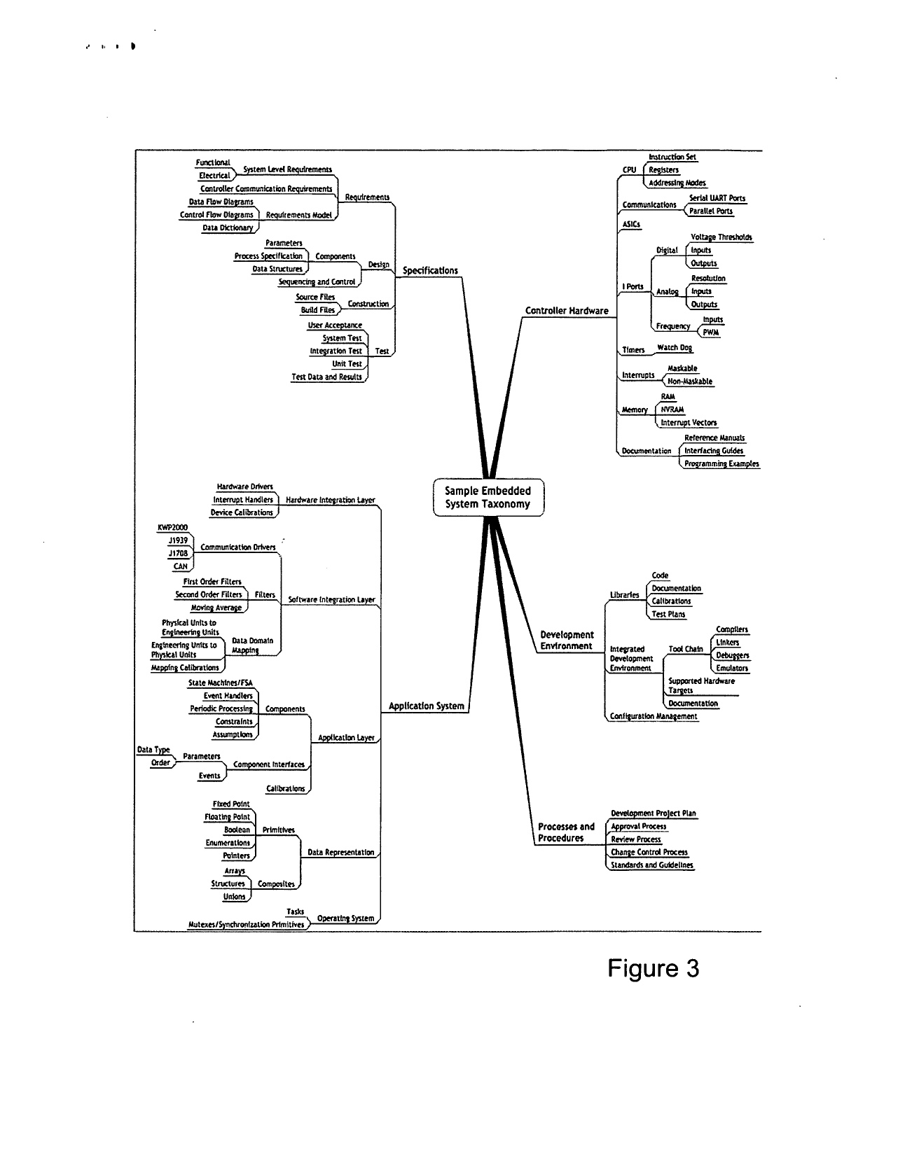

FIG. 3 graphically illustrates a sample taxonomy. The actual taxonomy will be larger and more specialized depending on the specific application (e.g., automotive vs. consumer electronics). However, the key components will be as described here, and the terms used are familiar to those who develop embedded systems.

The same taxonomy is also provided in a list form following the discussion below, for reference.

In block 2, based on the taxonomy 204, create a digital repository of historical solutions (frameworks) 212, preferably including source code, components, specifications, requirements, test plans, test results, calibrations, models, documentations, training material, budgets, and outcomes. This repository 212 serves as the basis for reuse, reducing the development time.

In block 3, based on the taxonomy 204, use computational linguistic techniques to develop linguistic rules 213 and semantically index the content of the solution repository 212. The linguistic rules can be developed in a commercial product, such as ClearForest or VisualText, and will operate on both documents and source code. These rules 213 process the text, allowing text analysis with search and navigation 214. Rules 213 semantically identify the key elements according to the taxonomy, and index them for future use. Thus, the users will be able to rapidly search existing source code and documentation for references, and/or rapidly navigate through the same. This block substantially reduces the effort in accessing reference material, comprehending past solutions, and applying best-practices.

Linguistic rules are logical expressions used by commercially available text analysis tools to identify and extract relevant information from textual data (e.g., forms, web pages, e-mails, and manuals). Text analysis tools use both syntactic and semantic analysis, as well as pattern matching. In this case, linguistic rules leverage the taxonomy 204 to search the project documents for pertinent information. The linguistic rules must be authored for the specific application (e.g., automotive) and may vary from company to company. Development of linguistic rules requires in-depth knowledge of embedded systems development as well as the application domain; those of skill in the art will have sufficient knowledge.

The following three examples demonstrate common patterns of rules:

1) <Name1> (<Variable_Name1>) is a linear calibratible function (<Calibration_Name>) of [<Name2>|<Function>].

Example text that follows the rule: “Suction pressure (Ve_p_vSuctionPress) is a linear calibratible function (Ka_p_cPct2SuctionPress) of the ratio of the filtered suction pressure sensor voltage (Ve_U_sSuctionPressFltrd) to filtered sensor supply voltage (Ve_U_sSnsrSplyFltrd).”

2) <Name1> (<Variable_Name1>) shall be controlled using <Control_Function> as a function of <Name2> (<Variable_Name2>) and <Name3> (<Variable_Name3>).

Example text that follows the rule: “Compressor capacity (Ve_Pct_vCmprssrCapcty) shall be controlled using a PID controller (with proportional gain Ke_k_cCmprssrPID_Prop, integral gain Ke_k_cCmprssrPID_Intgrl, and derivative gain Ke_k_cCmprssrPID_Deriv) as a function of desired suction pressure (Ve_p_cSuctionPressDsrd) and actual suction pressure (Ve_p_vSuctionPressActl).”

3) Every <Time_Period> <Source Type> <Variable_Name1> shall be <Operation_Name> to produce <Variable_Name2>.

Example text that follows the rule: “Every 25 msec the raw digital input Ve_b_sHVAC_DiagMd_shall be debounced to produce Ve_b_vHVAC_DiagMd.”

In each example, the rule guides the text analysis tool to identify and extract components, operations, data, relationships etc. The information identified here supports other function such as search and navigation as required by the application developer.

This capability offers significant utility to the developers because it eliminates the mundane and time consuming process of reading and searching multiple manuals, requirements, specifications, product information catalogs etc. for the required nuggets information.

Block 4 includes a process to develop an expert system 207 to select/configure/generate the initial framework 210 based on a knowledge base 209 including rules of configuration best-practices and using an inference engine. Expert system also receives requirements 205. The expert systems can be developed using commercial products such as CIA Server or Blaze Advisor; the rules are in the form of heuristics and developed based on the best-practices defined by the domain experts. The expert system provides a better starting point for the development process, and potentially reduces the development time by eliminating a number of design iterations.

The initial phase of developing embedded systems is usually based on re-using existing solutions and past designs. These solutions are stored in the Framework Repository 212. However, the challenge is the proper selection of the right components given the current requirements and constraints. This re-use activity is highly desirable, as it reduces development time, but it requires scarce expertise to ensure that the right components are selected and properly configured. The preferred embodiments capture and disseminate this scarce knowledge using an expert system. Expert systems consist of an inference engine (commercially available) and a knowledge-base (custom developed). The rules in expert systems are heuristics written in IF-THEN form. Unlike conventional programming languages, expert systems do not use rules to control the flow of the program; instead they use IF-THEN heuristics to infer new knowledge based on the known body of knowledge (the knowledge-base) and the available data.

The following examples illustrate 8 simple heuristics that can be used to configure an initial embedded application, in accordance with a preferred embodiment. In practice, the knowledge-base may consist of hundreds and thousands of these heuristics.

| | |
|---|---|
| 1. | IF system-uses-function(“PID_Controller”) THEN add- |
| | file(“PIDCntrlr.c”) |
| 2. | IF system-uses-function(“PIDCntrlr.c”) THEN add- |
| | file(“PIDCntrlr.h”) |
| 3. | IF system-uses-function(“PIDCntrlr.c”) THEN add- |
| | file(“CntrlLib.c”) |
| 4. | IF system-uses-function(“CntrlLib.c”) THEN add- |
| | file(“CntrlLib.h”) |
| 5. | IF system-uses-name(“Ka_p_cPct2Suctionpress”) THEN add- |
| | file(“SuctionPress.c”) |
| 6. | IF system-uses-file(“SuctionPress.c”) THEN add- |
| | file(“SuctionPress.h”) |
| 7. | IF system-uses-file(“SuctionPress.c”) THEN add- |
| | file(“SuctionPressCals.c”) |
| 8. | IF system-uses-file(“SuctionPressCals.c”) THEN add- |
| | file(“SystemConsts.h”) |

Block 5 includes a model 215 of the embedded systems extracted from the code to display system elements and relationships, using object-oriented interactive modeling. This feature provides the ability to manage complexity and dependencies between the elements, and thus reduce the customization time and improve quality. The model undergoes testing 220 and simulation 225.

In block 6, develop an initial calibration 227 using evolutionary computing techniques, such as a genetic algorithm, based on a fitness function derived from historical data and best-practices. The genetic algorithm can be implemented with a commercial product, such as MicroGA; the parametric representation can be composed of the calibration elements as defined in the taxonomy, and the fitness function will be based on rules and best-practices defined by domain experts. This feature reduces development time and potentially improves quality by providing a better starting point for calibration. Following initial calibration 227, conventional calibration 230 and test 235 are performed.

New embedded applications need to be calibrated for optimal performance. Calibration of embedded applications is complex and requires expert knowledge. The linear and non-linear influences among the parameters are generally known, but so numerous that can't be easily captured as rules. Experienced developers often start the calibration process by copying almost directly from prior systems, and then modify the parameters until the optimal configuration is discovered. The linguistic tools of the preferred embodiment provide the starting point more efficiently, by locating the ideal prior system to use, but the process of fine-tuning the parameters still remains. Genetic algorithms can be used to discover the optimal parameter setting (calibration). A genetic algorithm solution consists of an engine (commercially available), parameters to be optimized (project specific), and a fitness function (domain specific). Different application may require different fitness functions.

The following is a set of examples of parameters to be calibrated:

1. U_16_P_14 Ke_k_cCmprssrPID_Prop = 0x0666; /* 0.100 */
2. U_16_P_14 Ke_k_cCmprssrPID_Intgrl = 0x1000; /* 0.25 */
3. U_16_P_14 Ke_k_cCmprssrPID_Deriv = 0x0041; /* 0.004 */
4. U_16_P_4 Ka_p_cPct2SuctionPress [9] = {

| | | | | | |
|---|---|---|---|---|---|
| 0x00E0 | /* | 0% - | > | 14 kPa | */, |
| 0x0Ce0 | /* | 12.5% - | > | 200 kPa | */ |
| 0x15E0 | /* | 25.0% - | > | 350 kPa | */, |
| 0x2580 | /* | 37.5% - | > | 600 kPa | */, |
| 0x3520 | /* | 50.0% - | > | 850 kPa | */, |
| 0x50A0 | /* | 62.5% - | > | 1290 kPa | */, |
| 0x7760 | /* | 75.0% - | > | 1910 kPa | */, |
| 0xA5A0 | /* | 87.5% - | > | 2650 kPa | */, |
| 0xBB80 | /* | 100% - | > | 3000 kPa | */ }; |

The fitness function is generally a set of IF-THEN rules that fine tune the parameters. A sample rule is illustrated as:

IF Ke_k_cCmprssrPID_Prop > 0x0660 AND
Ka_p_cPct2SuctionPress [2] < 0x1600
THEN Ke_k_cCmprssrPID_Intgrl += 0x0001;

Thus, the linguistic tools (box 3) identify the closest match and set the initial search state, and the genetic algorithm, along with its fitness function will explore permutations of the parameters in a controlled random manner until the optimal settings are discovered, and the embedded system in calibrated. In practice, this calibration may be subject to further testing and validation, as known to those of skill in the art.

A genetic algorithm, as known to those of skill in the art, is an evolutionary algorithm which generates each individual from some encoded form known as a “chromosome” or “genome”. Chromosomes are combined or mutated to breed new individuals. “Crossover”, the kind of recombination of chromosomes found in sexual reproduction in nature, is often also used in genetic algorithms. Here, an offspring's chromosome is created by joining segments chosen alternately from each of two parents' chromosomes which are of fixed length. Genetic algorithms are useful for multidimensional optimization problems in which the chromosome can encode the values for the different variables being optimized.

Based on the framework, first an initial design 240 then a final design 245 are created. The final design 245 is stored in repository 212.

Some benefits of the proposed invention include:
Reduce embedded systems development time.
Reduce embedded systems development costs.
Improve embedded systems quality.

Further background information can be found in Holland J., Adaptation in Natural and Artificial Systems, 1975; Koza, Genetic Programming and Genetic Programming II, MIT Press, 1993 & 1994; Mitchell M., An Introduction to Genetic Algorithm, MIT Press, 1996; Michalewicz Z., Genetic Algorithm+Data Structures=Evolution, Springer Verlag, 1996; “Embedded Systems Design: An Introduction to Processes, Tools, and Techniques”, by Arnold S. Berger, CMP Books, ISBN: 1578200733; and “Strategies for Real-Time System Specification” by Hatley and Pirbhai, Dorset House Publishing Company, ISBN: 0932633110, all of which are hereby incorporated by reference. Further, a system and method for semantic software analysis is described in U.S. patent application Ser. No. 10/357,329, now published application 20040154000, which is hereby incorporated by reference.

Following is the exemplary taxonomy of FIG. 3, in list form:

Controller Hardware

| | |
|---|---|
| a. | CPU |

| | |
|---|---|
| i. | Instruction Set |
| ii. | Registers |
| iii. | Addressing Modes |

| | |
|---|---|
| b. | Communications |

| | |
|---|---|
| i. | Serial UART Ports |
| ii. | Parallel Ports |

| | |
|---|---|
| c. | ASICs |
| d. | Ports |

| | |
|---|---|
| i. | Digital |

| | |
|---|---|
| 1. | voltage Thresholds |
| 2. | Inputs |
| 3. | Outputs |

| | |
|---|---|
| ii. | Analog |

| | |
|---|---|
| 1. | Resolution |
| 2. | Inputs |
| 3. | Outputs |

| | |
|---|---|
| iii. | Frequency |

| | |
|---|---|
| 1. | Inputs |
| 2. | PWM |

| | |
|---|---|
| e. | Timers |

| | |
|---|---|
| i. | Watch Dog |

| | |
|---|---|
| f. | Interrupts |

| | |
|---|---|
| i. | Maskable |
| ii. | Non-Maskable |

| | |
|---|---|
| g. | Memory |

| | |
|---|---|
| i. | RAM |
| ii. | NVRAM |
| iii. | Interrupt Vectors |

| | |
|---|---|
| h. | Documentation |

| | |
|---|---|
| i. | Reference Manuals |
| ii. | Interfacing Guides |
| iii. | Programming Examples |

Development Environment

| | |
|---|---|
| a. | Libraries |

| | |
|---|---|
| i. | Code |
| ii. | Documentation |
| iii. | Calibrations |
| iv. | Test Plans |

| | |
|---|---|
| b. | Integrated Development Environment |

| | |
|---|---|
| i. | Tool Chain |

| | |
|---|---|
| 1. | Compilers |
| 2. | Linkers |
| 3. | Debuggers |
| 4. | Emulators |

| | |
|---|---|
| ii. | Supported Hardware Targets |
| iii. | Documentation |

| | |
|---|---|
| c. | Configuration Management |

Processes and Procedures

| | |
|---|---|
| a. | Development Project Plan |
| b. | Approval Process |
| c. | Review Process |
| d. | Change Control Process |
| e. | Standards and Guidelines |

Application System

| | |
|---|---|
| a. | Hardware Integration Layer |

| | |
|---|---|
| i. | Hardware Drivers |
| ii. | Interrupt Handlers |
| iii. | Device Calibrations |

| | |
|---|---|
| b. | Software Integration Layer |

| | |
|---|---|
| i. | Communication Drivers |

| | |
|---|---|
| 1. | KWP2000 |
| 2. | J1939 |
| 3. | J1708 |
| 4. | CAN |

| | |
|---|---|
| ii. | Filters |

| | |
|---|---|
| 1. | First Order Filters |
| 2. | Second Order Filters |
| 3. | Moving Average |

| | |
|---|---|
| iii. | Data Domain Mapping |

| | |
|---|---|
| 1. | Physical Units to Engineering Units |
| 2. | Engineering Units to Physical Units |
| 3. | Mapping Calibrations |

| | |
|---|---|
| c. | Application Layer |

| | |
|---|---|
| i. | Components |

| | |
|---|---|
| 1. | State Machines/FSA |
| 2. | Event Handlers |
| 3. | Periodic Processing |
| 4. | Constraints |
| 5. | Assumptions |

| | |
|---|---|
| ii. | Component Interfaces |

| | |
|---|---|
| 1. | Parameters |

| | |
|---|---|
| a. | Data Type |
| b. | Order |

| | |
|---|---|
| 2. | Events |

| | |
|---|---|
| iii. | Calibrations |

| | |
|---|---|
| d. | Data Representation |

| | |
|---|---|
| i. | Primitives |

| | |
|---|---|
| 1. | Fixed Point |
| 2. | Floating Point |
| 3. | Boolean |
| 4. | Enumerations |
| 5. | Pointers |

| | |
|---|---|
| ii. | Composites |

| | |
|---|---|
| 1. | Arrays |
| 2. | Structures |
| 3. | Unions |

| | |
|---|---|
| e. | Operating System |

| | |
|---|---|
| i. | Tasks |
| ii. | Mutexes/Synchronization Primitives |

Specifications

| | |
|---|---|
| a. | Requirements |

| | |
|---|---|
| i. | System Level Requirements |

| | |
|---|---|
| 1. | Functional |
| 2. | Electrical |

| | |
|---|---|
| ii. | Controller Communication Requirements |
| iii. | Requirements Model |

| | |
|---|---|
| 1. | Data Flow Diagrams |
| 2. | Control Flow Diagrams |
| 3. | Data Dictionary |

| | |
|---|---|
| b. | Design |

| | |
|---|---|
| i. | Components |

| | |
|---|---|
| 1. | Parameters |
| 2. | Process Specification |
| 3. | Data Structures |

| | |
|---|---|
| ii. | Sequencing and Control |

| | |
|---|---|
| c. | Construction |

| | |
|---|---|
| i. | Source Files |
| ii. | Build Files |

| | |
|---|---|
| d. | Test |

| | |
|---|---|
| i. | User Acceptance |
| ii. | System Test |
| iii. | Integration Test |
| iv. | Unit Test |
| v. | Test Data and Results |

Those skilled in the art will recognize that, for simplicity and clarity, the full structure and operation of all data processing systems suitable for use with the present invention is not being depicted or described herein. Indeed, the preferred embodiments can be implemented in well-known data processing systems, that may conform to any of the various current implementations and practices known in the art.

It is important to note that while the present invention has been described in the context of a fully functional system, those skilled in the art will appreciate that at least portions of the mechanism of the present invention are capable of being distributed in the form of a instructions contained within a machine usable medium in any of a variety of forms, and that the present invention applies equally regardless of the particular type of instruction or signal bearing medium utilized to actually carry out the distribution. Examples of machine usable mediums include: nonvolatile, hard-coded type mediums such as read only memories (ROMs) or erasable, electrically programmable read only memories (EEPROMs), user-recordable type mediums such as floppy disks, hard disk drives and compact disk read only memories (CD-ROMs) or digital versatile disks (DVDs), and transmission type mediums such as digital and analog communication links.

Although an exemplary embodiment of the present invention has been described in detail, those skilled in the art will understand that various changes, substitutions, variations, and improvements of the invention disclosed herein may be made without departing from the spirit and scope of the invention in its broadest form.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC §112 unless the exact words “means for” are followed by a participle.

1. A method for developing embedded systems, comprising:
developing a data dictionary and corresponding taxonomy;
creating a repository;
developing linguistic rules;
developing an expert system; and
creating a model of the embedded systems, using the expert system, taxonomy, repository, and rules.

2. The method of claim 1, further comprising calibrating and testing the model.

3. The method of claim 1, further comprising calibrating the model using a genetic algorithm.

4. The method of claim 1, wherein the repository includes embedded system source code.

5. The method of claim 1, wherein the repository includes embedded system documentation.

6. The method of claim 1, further comprising semantically indexing the content of the repository.

7. The method of claim 1, further comprising developing an initial framework of the embedded systems using the expert system.

8. The method of claim 7, wherein the expert system includes a knowledge base.

9. The method of claim 1, wherein the model displays elements and relationships of the embedded systems.

10. A computer program product tangibly embodied in a machine-readable medium, comprising:
instructions for developing a data dictionary and corresponding taxonomy;
instructions for creating a repository;
instructions for developing linguistic rules;
instructions for developing an expert system; and
instructions for creating a model of the embedded systems, using the expert system, taxonomy, repository, and rules.

11. The computer program product of claim 10, further comprising instructions for calibrating and testing the model.

12. The computer program product of claim 10, further comprising instructions for calibrating the model using a genetic algorithm.

13. The computer program product of claim 10, wherein the repository includes embedded system source code.

14. The computer program product of claim 10, wherein the repository includes embedded system documentation.

15. The computer program product of claim 10, further comprising instructions for semantically indexing the content of the repository.

16. The computer program product of claim 10, further comprising instructions for developing an initial framework of the embedded systems using the expert system.

17. The computer program product of claim 10, wherein the model displays elements and relationships of the embedded systems.
